(19) United States
(12) Patent Application Publication
(10) Pub. No.: US 2025/0221114 A1
(43) Pub. Date: Jul. 3, 2025

(54) DISPLAY DEVICE

(71) Applicant: LG Display Co., Ltd., Seoul (KR)

(72) Inventors: Suk Choi, Hwaseong-si (KR); SeYeoul Kwon, Paju-si (KR); GyuHo Lee, Seoul (KR); Miyeon Seo, Seoul (KR); Chaeyoung Son, Seoul (KR)

(73) Assignee: LG Display Co., Ltd., Seoul (KR)

(21) Appl. No.: 18/921,895

(22) Filed: Oct. 21, 2024

(30) Foreign Application Priority Data
Dec. 27, 2023 (KR) 10-2023-0192315

(51) Int. Cl. H01L 33/54; H01L 25/16; H01L 33/62; H10K 59/80; H10K 102/00

(52) U.S. Cl. CPC H10H 20/853; H01L 25/167; H10H 20/857; H10K 59/873; H10K 2102/311

(57) ABSTRACT

Provided is a display device. The display device includes a flexible substrate including an active area and a non-active area which encloses the active area; a light emitting diode disposed on the flexible substrate; a thin film glass disposed on the light emitting diode; and a first electrode disposed on a top surface of the thin film glass, in the non-active area. Accordingly, an electrode which is disposed in a thin film glass easily detects a micro-crack which occurs in the thin film glass.

### CROSS-REFERENCE TO RELATED APPLICATIONS

This application claims the priority of Korean Patent Application No. 10-2023-0192315 filed on 27 Dec. 2023, in the Korean Intellectual Property Office, the disclosure of which is incorporated herein by reference.

### BACKGROUND

### Technical Field

The present disclosure relates to a display device and more particularly, to a display device which minimizes a crack of a cover glass.

### Discussion of the Related Art

A display field has been rapidly developed, and in response to this, various display devices having excellent performances such as thin-thickness, light weight, and low power have been developed. Specific examples of such a display device include a liquid crystal display (LCD) device, a plasma display panel (PDP) device, a field emission display (FED) device, an organic light emitting display (OLED) device, and the like. Recently, a shape or a size of the display device has gradually diversified and in particularly, an interest in a flexible display device which maintains a display performance even though the display device is folded or rolled is consistently increasing. In accordance with this interest, researches and development on panels, fixtures, and cover windows having a specific radius of curvature are being actively conducted.

Specifically, the cover window is a component which is exposed to a user from an outer periphery of the display device. Accordingly, a cover glass having a more excellent appearance characteristic than a plastic cover window is desirably used. Due to the characteristic of the glass, when the thickness is limited to 0.1 mm or less, the cover window may have a folding characteristic. Due to this, even though the rigidity of the glass itself is considerably superior to the plastic, as mentioned above, the impact resistance is inferior to that of the plastic cover window in which the thickness may be freely designed within a limited thickness. Accordingly, the importance of suppressing and detecting a crack which may occur on a cover glass during a manufacturing process is increasing.

### SUMMARY

Accordingly, embodiments of the present disclosure are directed to a display device that substantially obviates one or more of the problems due to limitations and disadvantages of the related art.

An aspect of the present disclosure is to provide a display device including a cover glass from which a crack is easily detected.

Another aspect of the present disclosure is to provide a display device which uses a cover glass with an excellent surface characteristic and has an excellent impact resistance.

Still another aspect of the present disclosure is to provide a display device which improves durability and reliability by suppressing a crack of a cover glass.

Still another aspect of the present disclosure is to provide a display device which improves a folding characteristic while reducing a folding stress.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a flexible substrate including an active area and a non-active area which encloses the active area; a light emitting diode disposed on the flexible substrate; a thin film glass disposed on the light emitting diode; and a first electrode disposed on a top surface of the thin film glass, in the non-active area. Accordingly, an electrode which is disposed in a thin film glass easily detects a micro-crack which occurs in the thin film glass.

Other detailed matters of the exemplary embodiments are included in the detailed description and the drawings.

According to the present disclosure, a corner of a thin film glass is formed to be chambered to reduce a folding stress and improve a folding characteristic.

According to the present disclosure, an electrode is disposed in a thin film glass to easily detect a micro-crack which occurs in the thin film glass.

According to the present disclosure, a crack of a thin film glass is suppressed to improve the durability and the reliability of the display device.

It is to be understood that both the foregoing general description and the following detailed description are exemplary and explanatory and are intended to provide further explanation of the inventive concepts as claimed.

### BRIEF DESCRIPTION OF DRAWINGS

accompanying drawings, which are included to provide a further understanding of the disclosure and are incorporated in and constitute a part of this application, illustrate embodiments of the disclosure and together with the description serve to explain various principles. In the drawings:

FIG. 1 is a plan view of a display device according to an exemplary embodiment of the present disclosure;

FIG. 2 is a cross-sectional view taken along the line II-II′ of FIG. 1;

FIG. 3 is a cross-sectional view of a cover glass of a display device according to an exemplary embodiment of the present disclosure;

FIG. 4 is a cross-sectional view of a cover glass of a display device according to another exemplary embodiment of the present disclosure;

FIG. 5 is a cross-sectional view of a cover glass of a display device according to still another exemplary embodiment of the present disclosure;

FIG. 6 is a cross-sectional view of a cover glass of a display device according to still another exemplary embodiment of the present disclosure;

FIG. 7A is a plan view of a cover glass of a display device according to still another exemplary embodiment of the present disclosure;

FIG. 7B is a cross-sectional view taken along VII-VII′ of FIG. 7A;

FIG. 8 is a plan view of a cover glass of a display device according to still another exemplary embodiment of the present disclosure; and

FIG. 9 is a plan view of a cover glass of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

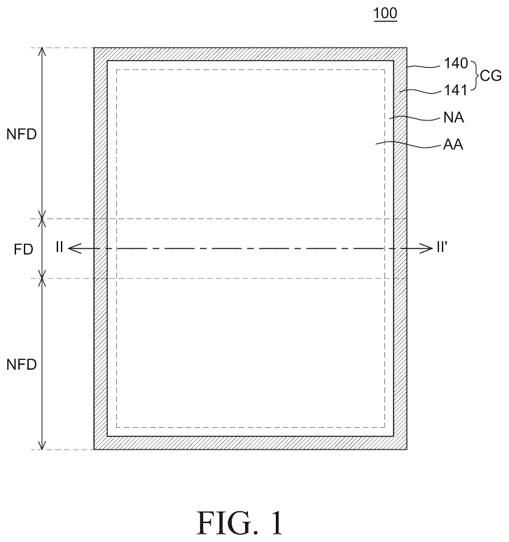

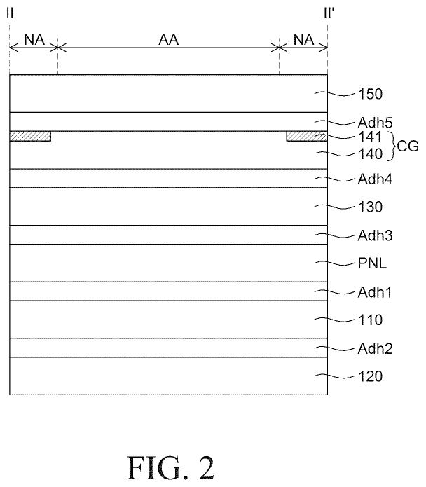

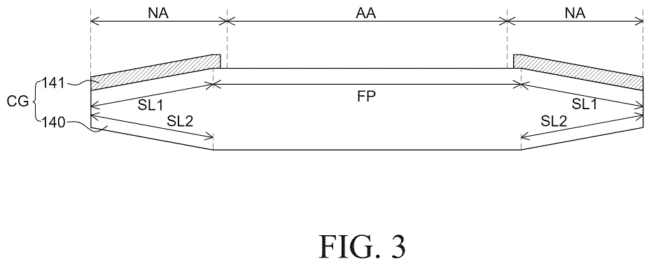

FIG. 1 is a plan view of a display device according to an exemplary embodiment of the present disclosure. FIG. 2 is a cross-sectional view taken along the line II-II′ of FIG. 1. FIG. 3 is a cross-sectional view of a cover glass of a display device according to an exemplary embodiment of the present disclosure.

Referring to FIGS. 1 and 2, a display device 100 according to the exemplary embodiment of the present disclosure may include a back plate 110, a bottom cover 120, a display panel PNL, a polarization layer 130, a cover glass CG, and a protective film 150. The cover glass CG may include a thin film glass 140 and a first electrode 141.

First, referring to FIG. 1, the display panel PNL may include a flexible substrate and a light emitting diode.

The flexible substrate may include at least one folding area FD and two or more non-folding areas NFD. The folding area FD is an area which is folded when the display device 100 is folded and is folded along a specific radius of curvature with respect to a folding axis FA. The non-folding area NFD is an area which is not folded when the display device 100 is folded. That is, the non-folding area NFD may maintain a flat state when the display device 100 is folded. The non-folding area NFD may be located on both sides of the folding area FD.

When the display device 100 is folded, the folding area FD is folded with respect to the folding axis and the folding area FD may form a part of a circle or an oval. At this time, a radius of curvature of the folding area FD may refer to a radius of a circle or an oval formed by the folding area. When the folding area FD is folded with respect to the folding axis, the non-folding areas NFD overlap each other. A top surface of the display device 100 on which images are displayed is defined as a display surface and a bottom surface of the display device 100 which is an opposite surface of the display surface is defined as a rear surface. At this time, the folding area FD may be folded by a method selected from an out-folding method and an in-folding method. According to the out-folding method, the folding area is folded to expose the display surface of the display device 100 to the outside. According to the in-folding method, the folding area is folded such that display surfaces of the display device 100 face each other.

The flexible substrate may include an active area AA and a non-active area NA.

The active area AA is an area where a plurality of pixels is disposed to display images. In the active area AA, pixels including an emission area for displaying images and a driving circuit for driving the pixels may be disposed. The non-active area NA may be disposed so as to enclose the active area AA.

The non-active area NA is an area where no image is displayed and various wiring lines, driving ICs, printed circuit boards, and the like for driving the pixels disposed in the active area AA and the driving circuits are disposed.

The flexible substrate may support various components which configure the display panel PNL. The flexible substrate may be a plastic substrate having flexibility. For example, the plastic substrate may be selected from polyimide, polyethersulfone, polyethylene terephthalate, and polycarbonate, but is not limited thereto. The plastic substrate has a relatively weak barrier characteristic against moisture or oxygen so that in order to compensate therefor, the plastic substrate may have a structure in which a plastic film and an inorganic film are laminated. For example, the flexible substrate may have a multi-layered structure in which a first polyimide film, an inorganic film, and a second polyimide film are sequentially laminated, but is not limited thereto.

A light emitting diode may be disposed on the flexible substrate. The light emitting diode may be defined in different manners depending on the type of the display panel PNL. For example, when the display panel PNL is an inorganic light emitting display panel, the light emitting diode may be a light emitting diode (LED) or a micro light emitting diode (LED). Further, when the display panel PNL is an organic light emitting display panel, the light emitting diode may be an organic light emitting diode (OLED).

A driving transistor may be disposed between the flexible substrate and the light emitting diode to drive the light emitting diode. The driving transistor may be disposed in each of the plurality of sub pixel areas. For example, the driving transistor may include a gate electrode, an active layer, a source electrode, and a drain electrode. Further, the driving transistor may further include a gate insulating layer which insulates the gate electrode from the active layer and an interlayer insulating layer which insulates the gate electrode from the source electrode and the drain electrode.

Various support members may be disposed below the display panel PNL. For example, a back plate 110 and a bottom cover 120 may be disposed below the display panel PNL.

The back plate 110 supports the display panel PNL and may protect the display panel PNL from external moisture, heat, and shocks. For example, the back plate 110 may be a metal material such as stainless steel (SUS) or Invar and may be formed of a plastic such as polymethylmetacrylate (PMMA), polycarbonate (PC), polyvinylalcohol (PVA), acrylonitrilebutadiene-styrene (ABS), polyethylene terephthalate (PET), silicone, or polyurethane (PU), but it is not limited thereto.

A first adhesive layer Adh1 may be disposed between the back plate 110 and the display panel PNL. The first adhesive layer Adh1 may be formed of a pressure sensitive adhesive (PSA), but is not limited thereto.

The bottom cover 120 may be disposed on the bottom surface of the back plate 110. For example, the bottom cover 120 may be a metal such as stainless steel (SUS) or Invar and may be formed of a plastic material such as polymethylmetacrylate (PMMA), polycarbonate (PC), polyvinylalcohol (PVA), acrylonitrilebutadiene-styrene (ABS), polyethylene terephthalate (PET), silicone, or polyurethane (PU), but it is not limited thereto. The bottom cover 120 may include at least one opening pattern corresponding to the folding area of the display device 100. The opening pattern allows the bottom cover 120 of the folding area to be easily folded and may effectively relieve the stress applied to the bottom cover 120 during the folding. Further, the folding characteristic of the display device 100 may be improved by easily being restored after the folding. The opening patterns may be formed with different shapes or different intervals in the folding area. For example, the opening pattern may have a rectangular shape, a rhombus shape, or a circular shape, but it is not limited thereto.

A second adhesive layer Adh2 may be disposed between the back plate 110 and the bottom cover 120. The second adhesive layer Adh2 may be an optically clear adhesive (OCA) which minimizes foreign particles or bubbles generated between the back plate 110 and the bottom cover 120, but is not limited thereto.

A polarization layer 130 may be disposed on the display panel PNL. The polarization layer 130 is a layer for planarizing incident light and may include a polarizer which is a film having a predetermined level of light transmittance to absorb external light and reflected light thereof to suppress degradation of a contrast ratio. That is, a degradation of a display quality due to reflected light of the external light is suppressed and a transmittance of an image of the display device may be improved.

A third adhesive layer Adh3 may be disposed between the display panel PNL and the polarization layer 130. The third adhesive layer Adh3 may be an optically clear adhesive layer (OCA) which minimizes foreign particles or bubbles generated between the display panel PNL and the polarization layer 130, but is not limited thereto.

A cover glass CG may be disposed on the display panel PNL. The cover glass CG may protect the display panel PNL so as not to be damaged by an external impact or deteriorated by moisture, oxygen, or foreign substances entering from the outside. The cover glass CG may include a thin film glass 140 and a first electrode 141.

The thin film glass 140 may have a thickness of 30 μm to 90 μm. The thin film glass 140 having such a thickness has an advantage of excellent folding characteristic. The thin film glass 140 may be a chemically strengthened glass. The chemically strengthened glass is a glass which is strengthened by a chemical strengthening method. The chemical strengthening method is a process of enhancing the strength of the glass by an ion exchange method which replaces sodium ions included in the glass with ions having an ion radius larger than that of the sodium ions. Ions having an ion radius larger than that of sodium ions which configure the glass are permeated so that a compressive stress layer is formed on the glass surface to enhance the strength. For example, the chemically strengthened glass may be prepared by a process of immersing glass in a potassium salt solution such as potassium nitride and substituting the sodium ions of the glass with potassium ions while heating at 200° C. to 450° C. for a predetermined time, but is not limited thereto. 200° C. to 450° C. is a temperature which is equal to or lower than a glass transition temperature.

Referring to FIG. 3, the thin film glass 140 may have a chamfered corner. As described above, when the thin film glass 140 has a chamfered shape, a folding stress which is further concentrated on a corner portion during the folding or bending may be reduced and the folding characteristic of the display device 100 may be further improved.

The chamfered shape may be formed by etching a predetermined depth from a side surface of the glass to a glass surface. For example, the thin film glass 140 having a chamfered shape is formed by a healing process of chemically etching glass. Specifically, after laminating glass which is cut in cell units as a plurality of layers, when a top surface and a bottom surface of the laminated glass are attached to a protecting layer, for example, a dummy film and then immersed in an etchant, a side surface of the glass which is exposed to the etchant is etched. Further, the etchant penetrates into a gap between the laminated glasses so that the side surface of the laminated thin film glass 140 has a chamfered shape.

The thin film glass 140 is etched from a surface of the thin film glass 140 at the corner of the thin film glass 140, by a predetermined depth, by the healing process to have a chamfered shape. Therefore, the thin film glass 140 may include a flat portion FP and an inclined portion which is formed by etching the thin film glass from a surface at a predetermined angle. The inclined portion may include a first inclined portion SL1 formed on a top surface of the thin film glass 140 and a second inclined portion SL2 formed on a bottom surface of the thin film glass 140. The first inclined portion SL1 formed on the top surface of the thin film glass 140 and the second inclined portion SL2 formed on the bottom surface of the thin film glass 140 have the same inclination angle. In the meantime, even though in FIG. 3, it is illustrated that both the first inclined portion SL1 and the second inclined portion SL2 are formed, only one of the first inclined portion SL1 and the second inclined portion SL2 may be formed. At this time, the inclined portion of the thin film glass 140 may be formed in the non-active area NA and may connect a corner of the flat portion FP and a side surface of the thin film glass 140. In the meantime, the flat portion FP may be disposed in a portion adjacent to the active area AA, between the active area AA and the non-active area NA.

Referring to FIGS. 1 to 3, the first electrode 141 may be disposed on the thin film glass 140. The first electrode 141 is disposed on the top surface of the thin film glass 140 in the non-active area NA to easily detect a crack generated in the thin film glass 140. Therefore, the first electrode 141 may be disposed at the corner of the thin film glass 140 which is more vulnerable to the shocks. That is, the first electrode 141 may be disposed in the non-active area NA extending along at least one corner of the top surface of thin film glass 140. Even though in FIG. 1, it is illustrated that the first electrode 141 is disposed at four corners of the top surface of the thin film glass 140, it is not limited thereto so that the first electrode may be disposed only at some corner. Specifically, the first electrode 141 may be disposed on the first inclined portion SL1 of the thin film glass 140 in the non-active area NA. At this time, the first electrode 141 may extend to be disposed on the flat portion FP of the thin film glass 140. As the first electrode 141 is disposed on the flat portion FP, the crack which propagates to a portion adjacent to the active area AA may be detected.

The first electrode 141 detects a crack depending on whether liquid crystal of a crack detecting unit is driven, so that the first electrode 141 may be a transparent electrode. For example, the first electrode 141 may use an opaque conductive layer, such as aluminum (Al), titanium (Ti), or an alloy thereof and a transparent conductive layer, such as indium-tin-oxide (ITO), indium-zinc-oxide (IZO), indium gallium zinc oxide (IGZO), but is not limited thereto. Further, the first electrode 141 may be a floated electrode which is not electrically connected to a transistor, a wiring line, or the like. For example, a voltage is not applied to the first electrode 141, but is applied only to an electrode of the crack detecting unit and for example, a voltage of 100 V to 300 V is applied to the crack detecting unit, but is not limited thereto.

That is, the liquid crystal may be driven depending on a voltage difference of the first electrode 141 and the crack detecting unit. At this time, when the thin film glass 140 is cracked, the liquid crystal is not driven in the crack occurring area so that an area where the crack occurs may be detected depending on whether the liquid crystal of the crack detecting unit is driven.

Accordingly, when the crack of the thin film glass 140 is detected, a voltage application ratio of the crack detecting unit may vary depending on a distance between the crack detecting unit and the first electrode 141, but is not limited thereto. However, it is not limited thereto and the voltage may be also applied to the first electrode 141.

A refractive index of the first electrode 141 may be different from a refractive index of the thin film glass 140. Specifically, the refractive index of the first electrode 141 may be larger than the refractive index of the thin film glass 140. In this case, it may be specifically effective for a method of detecting a crack by recognizing a difference in refractive indexes of a portion where the crack occurs and a portion where no crack occurs using a reflector or a band pass filter (BPF), rather than a liquid crystal driving method.

Referring to FIG. 1 again, a protective film 150 may be disposed on the cover glass CG. The protective film 150 protects the display panel PNL from external shocks, scratches, foreign materials, or the like, and may suppress the scattering of the fragments when the thin film glass 140 is broken. The protective film 150 may be a plastic film including one or more kinds selected from polyethylene terephthalate (PET), polyethylene naphthalate (PEN), polyethylene (PE), poly(methyl methacrylate) (PMMA), polyimide (PI), polyamide-imide (PAI), polycarbonate (PC), and cycloolefin (co) polymer, but is not limited thereto.

Generally, a crack may occur in the thin film glass due to the external shock during the manufacturing process. The flexible display device uses a thin film glass with a thickness of 0.1 mm or less to improve the folding characteristic so that it is more vulnerable to the crack. Specifically, in order to improve the folding characteristic, the corner of the thin film glass may be chamfered. Therefore, during the process of etching a chamfered shape, micro crack may occur on the thin film glass and the micro crack formed in the non-active area may propagate the active area. When the crack occurs in the thin film glass, the foreign materials enter through a crack to cause a defect of the display device. At this time, a crack of the thin film glass may be detected using a tester including a TFT tester or a reflector, or a band pass filter (BPF). In the case of the TFT tester which detects the crack using a liquid crystal driving method, liquid crystal molecules of TFT tester are driven by applying a voltage to the TFT and the wiring line to detect the defect of the TFT and the wiring line. However, it is difficult to detect a crack generated in an outer peripheral portion of a panel in which a wiring line is not provided, that is, a non-active area and the crack generated after the TFT process may not be detected.

In the meantime, when a tester including a reflector or a band pass filter (BPF) is used, a camera recognizes a color difference due to a difference in refractive indexes of a light source reflected from a portion in which a crack occurs and a portion in which a crack does not occur to detect the defect. However, when a size of the crack is too small, from a few μm to several tens μm, the change in the refractive index is small so that the color change may not be recognized. Therefore, the defect may not be detected.

Therefore, in the display device 100 according to the exemplary embodiment of the present disclosure, in the non-active area NA, the first electrode 141 may be disposed on the top surface of the thin film glass 140 to detect the crack of the thin film glass 140. At this time, the liquid crystal of the crack detecting unit may be driven by a voltage difference of the first electrode 141 and the electrode of the crack detecting unit. At this time, when the crack occurs in the area of the thin film glass 140 in which the first electrode 141 is disposed, the liquid crystal of the crack detecting unit is not driven in the area in which the crack occurs. Accordingly, in the display device 100 according to the exemplary embodiment of the present disclosure, an area in which the liquid crystal of the crack detecting unit is not driven may be detected to easily detect the crack of the thin film glass 140.

In the display device 100 according to the exemplary embodiment of the present disclosure, the corner of the thin film glass 140 is formed to be chamfered to reduce a folding stress concentrated on the corner of the thin film glass 140 and improve the folding characteristic.

In the display device 100 according to the exemplary embodiment of the present disclosure, the first electrode 141 is disposed on the inclined portion SL vulnerable to the external shock, among chamfered corners of the thin film glass 140 to easily detect the crack.

That is, in the display device 100 according to the exemplary embodiment of the present disclosure, the first electrode 141 is disposed on the thin film glass 140 to suppress the crack from occurring and minimize the penetration of foreign materials through the crack to improve the durability and the reliability.

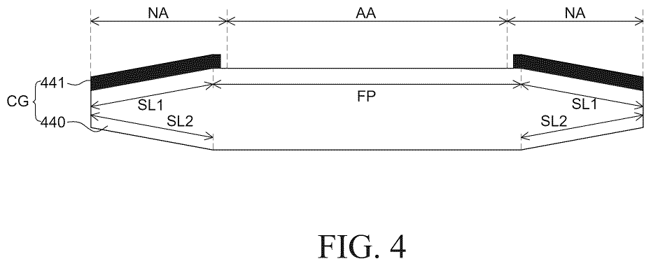

FIG. 4 is a cross-sectional view of a cover glass of a display device according to another exemplary embodiment of the present disclosure. The only difference between a cover glass CG of FIG. 4 and a cover glass CG of the display device 100 of FIGS. 1 to 3 is a first electrode 441, but other configuration is substantially the same, so that a redundant description will be omitted.

Referring to FIG. 4, a first electrode 441 is formed of a material including a black metal. The first electrode 441 is disposed on the thin film glass 140 to easily detect a crack occurring in the thin film glass 440. The first electrode 441 including a black metal suppresses not only the increase of a leakage current of the driving transistor by an external light source, but also light leakage. In the meantime, even though it is not illustrated in the drawing, the first electrode 441 may be disposed not only on a top surface of the thin film glass 440, but also on a bottom surface to easily detect the crack.

Therefore, in the display device according to another exemplary embodiment of the present disclosure, in the non-active area NA, the first electrode 441 may be disposed on the top surface of the thin film glass 440 to detect the crack of the thin film glass 440. At this time, the liquid crystal of the crack detecting unit may be driven by a voltage difference of the first electrode 441 and the electrode of the crack detecting unit. At this time, when the crack occurs in the area of the thin film glass 440 in which the first electrode 441 is disposed, the liquid crystal of the crack detecting unit is not driven in the area in which the crack occurs. Accordingly, in the display device according to another exemplary embodiment of the present disclosure, an area in which the liquid crystal of the crack detecting unit is not driven is detected to easily detect the crack of the thin film glass 440.

Further, in the display device according to another exemplary embodiment of the present disclosure, the first electrode 441 is disposed on a corner of the thin film glass 440 which is specifically vulnerable to the external shocks to suppress the crack from occurring and minimize the penetration of foreign materials through the crack to improve the durability and the reliability.

Specifically, in the display device according to another exemplary embodiment of the present disclosure, the first electrode 441 includes a black metal so that the leakage current of the driving transistor and a light leakage due to the external light source may be suppressed.

Further, in the display device according to another exemplary embodiment of the present disclosure, the first electrode 441 includes a black metal so that components such as wiring lines disposed in the non-active area NA may not be visible to the outside.

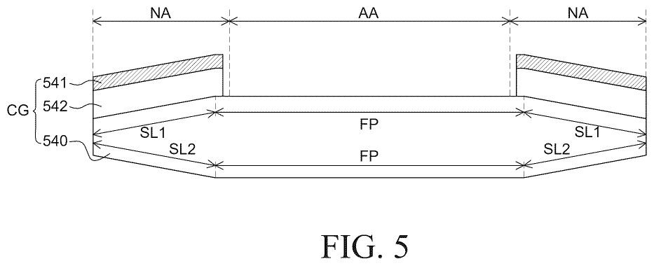

FIG. 5 is a cross-sectional view of a cover glass of a display device according to still another exemplary embodiment of the present disclosure. The only difference between a cover glass CG of FIG. 5 and a cover glass CG of the display device 100 of FIGS. 1 to 3 is presence of an organic layer 542, but other configuration is substantially the same, so that a redundant description will be omitted.

An organic layer 542 may be disposed between the thin film glass 540 and the first electrode 541. Specifically, the organic layer 542 may be disposed so as to overlap the first electrode 541. When the organic layer 542 detects a crack using a difference in refractive indexes of a portion in which a crack occurs and a portion in which a crack does not occur, the organic layer maximizes the difference in refractive indexes to easily detect the crack. Therefore, the organic layer 542 may be formed of a material having a larger refractive index. For example, the organic layer 542 may be formed of a material having a refractive index of 1.5 to 1.6, but is not limited thereto. In the meantime, even though it is not illustrated in the drawing, the first electrode 541 and the organic layer 542 may be disposed not only on a top surface of the thin film glass 540, but also on a bottom surface to easily detect the crack.

Therefore, in the display device according to another exemplary embodiment of the present disclosure, in the non-active area NA, the first electrode 541 may be disposed on the top surface of the thin film glass 540 to detect the crack of the thin film glass 540. At this time, the liquid crystal of the crack detecting unit may be driven by a voltage difference of the first electrode 541 and the electrode of the crack detecting unit. At this time, when the crack occurs in the area of the thin film glass 540 in which the first electrode 541 is disposed, the liquid crystal of the crack detecting unit is not driven in the area in which the crack occurs. Accordingly, in the display device according to the exemplary embodiment of the present disclosure, an area in which the liquid crystal of the crack detecting unit is not driven is detected to easily detect the crack of the thin film glass 540.

Further, in the display device according to still another exemplary embodiment of the present disclosure, the first electrode 541 is disposed on a corner of the thin film glass 540 which is specifically vulnerable to the external shocks to suppress the crack from occurring and minimize the penetration of foreign materials through the crack to improve the durability and the reliability.

Specifically, in the display device according to still another exemplary embodiment of the present disclosure, an organic layer 542 having a high refractive index is disposed between the thin film glass 540 and the first electrode 541. Therefore, it is effective for a crack detecting method using a difference in refractive indexes of a portion in which a crack occurs and a portion in which no crack occurs.

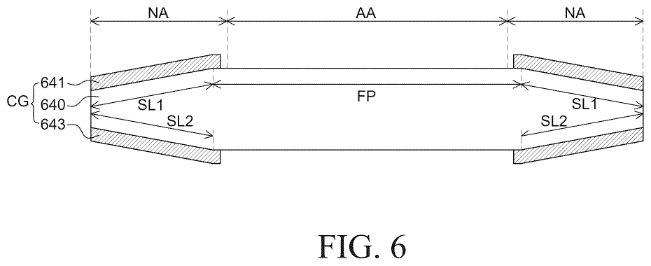

FIG. 6 is a cross-sectional view of a cover glass of a display device according to still another exemplary embodiment of the present disclosure. The only difference between a cover glass CG of FIG. 6 and a cover glass CG of the display device 100 of FIGS. 1 to 3 is presence of a second electrode 643, but other configuration is substantially the same, so that a redundant description will be omitted.

Referring to FIG. 6, a second electrode 643 may be disposed on a bottom surface of the thin film glass 640 in the non-active area NA. The second electrode 643 is disposed on the bottom surface of the thin film glass 140 to easily detect a crack generated in the thin film glass 640. Therefore, the second electrode 643 may be disposed at the corner of the bottom surface of the thin film glass 640 which is more vulnerable to the shocks. Specifically, the second electrode 643 may be disposed on the inclined surface SL2 of the corner of the bottom surface of the thin film glass 640. At this time, similar to the first electrode, the second electrode 643 may extend to be disposed on the flat portion FP. In the meantime, the second electrode 643 may be formed of the same material as the first electrode 641.

Therefore, in the display device according to another exemplary embodiment of the present disclosure, in the non-active area NA, the first electrode 641 may be disposed on the top surface of the thin film glass 640 to detect the crack of the thin film glass 640. At this time, the liquid crystal of the crack detecting unit may be driven by a voltage difference of the first electrode 641 and the electrode of the crack detecting unit. At this time, when the crack occurs in the area of the thin film glass 640 in which the first electrode 641 is disposed, the liquid crystal of the crack detecting unit is not driven in the area in which the crack occurs. Accordingly, in the display device according to the exemplary embodiment of the present disclosure, an area in which the liquid crystal of the crack detecting unit is not driven is detected to easily detect the crack of the thin film glass 640.

Further, in the display device according to still another exemplary embodiment of the present disclosure, the first electrode 641 is disposed at a corner of the thin film glass 640 which is specifically vulnerable to the external shocks to suppress the crack from occurring and minimize the penetration of foreign materials through the crack to improve the durability and the reliability.

Specifically, in the display device according to still another exemplary embodiment of the present disclosure, a second electrode 643 which is the same as the first electrode 641 is additionally disposed on the bottom surface of the thin film glass 640 as a double electrodes to further effectively detect the crack and suppress the crack.

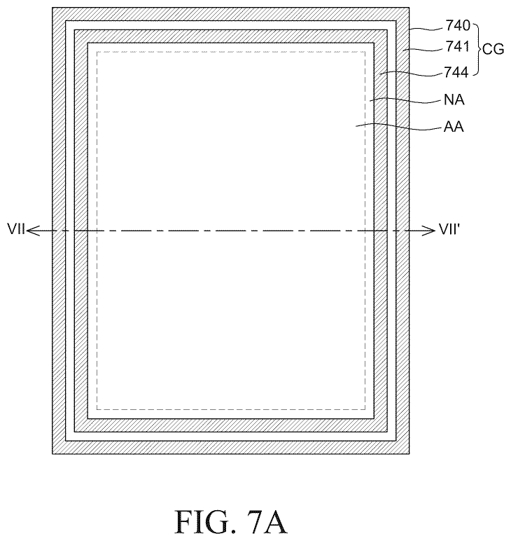

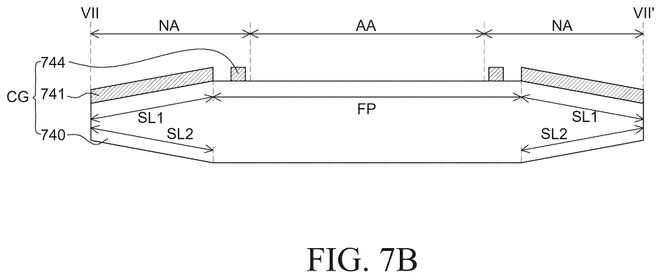

FIG. 7A is a plan view of a cover glass of a display device according to still another exemplary embodiment of the present disclosure. FIG. 7B is a cross-sectional view taken along VII-VII′ of FIG. 7A. The only difference between a cover glass CG of FIGS. 7A and 7B and a cover glass CG of the display device 100 of FIGS. 1 to 3 is presence of a sub electrode 744, but other configuration is substantially the same, so that a redundant description will be omitted.

Referring to FIGS. 7A and 7B, in the non-active area NA, the sub electrode 744 may be disposed in the first electrode 741. Specifically, the sub electrode 744 is spaced apart from the first electrode 741 to be disposed on the flat portion FP. Therefore, the sub electrode 744 may easily detect a crack which propagates to a position adjacent to the active area AA. A thickness and a width of the sub electrode 744 may be formed to be different from a thickness and a width of the first electrode 741 according to a crack detecting area. The sub electrode 744 may be formed of the same material as the first electrode 741.

Therefore, in the display device according to another exemplary embodiment of the present disclosure, in the non-active area NA, the first electrode 741 may be disposed on the top surface of the thin film glass 740 to detect the crack of the thin film glass 740. At this time, the liquid crystal of the crack detecting unit may be driven by a voltage difference of the first electrode 741 and the electrode of the crack detecting unit. At this time, when the crack occurs in the area of the thin film glass 740 in which the first electrode 741 is disposed, the liquid crystal of the crack detecting unit is not driven in the area in which the crack occurs. Accordingly, in the display device according to still another exemplary embodiment of the present disclosure, an area in which the liquid crystal of the crack detecting unit is not driven is detected to easily detect the crack of the thin film glass 740.

Further, in the display device according to still another exemplary embodiment of the present disclosure, the first electrode 741 is disposed on a corner of the thin film glass 740 which is specifically vulnerable to the external shocks to suppress the crack from occurring and minimize the penetration of foreign materials through the crack to improve the durability and the reliability.

Specifically, in the display device according to still another exemplary embodiment of the present disclosure, a sub electrode 744 is disposed in the first electrode 741 as a double electrode to expand a crack detecting area to easily figure out a crack propagating position.

That is, in the display device according to still another exemplary embodiment of the present disclosure, the sub electrode 744 is further disposed on the flat portion FP to easily detect a crack which propagates to a position adjacent to the active area AA.

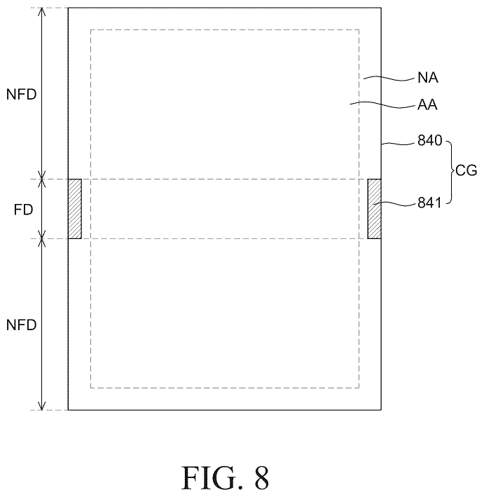

FIG. 8 is a plan view of a cover glass of a display device according to still another exemplary embodiment of the present disclosure. The only difference between a cover glass CG of FIG. 8 and a cover glass CG of the display device 100 of FIGS. 1 to 3 is a first electrode 841, but other configuration is substantially the same, so that a redundant description will be omitted.

Referring to FIG. 8, a first electrode 841 may be disposed on a top surface of a thin film glass 840 corresponding to a folding area FD in the non-active area NA. In the flexible substrate, a folding stress is concentrated in the folding area FD to be more vulnerable to the crack occurrence. Therefore, the first electrode 841 is disposed on the top surface of the thin film glass 840 corresponding to the folding area FD to easily detect a crack generated in the thin film glass 840.

In the display device according to still another exemplary embodiment of the present disclosure, in the non-active area NA, the first electrode 841 may be disposed on the top surface of the thin film glass 840 to detect the crack of the thin film glass 840. At this time, the liquid crystal of the crack detecting unit may be driven by a voltage difference of the first electrode 841 and the electrode of the crack detecting unit. At this time, when the crack occurs in the area of the thin film glass 840 in which the first electrode 841 is disposed, the liquid crystal of the crack detecting unit is not driven in the area in which the crack occurs. Accordingly, in the display device according to still another exemplary embodiment of the present disclosure, an area in which the liquid crystal of the crack detecting unit is not driven is detected to easily detect the crack of the thin film glass 840.

Further, in the display device according to still another exemplary embodiment of the present disclosure, the first electrode 841 is disposed on a corner of the thin film glass 840 which is specifically vulnerable to the external shocks to suppress the crack from occurring and minimize the penetration of foreign materials through the crack to improve the durability and the reliability.

Specifically, in the display device according to still another exemplary embodiment of the present disclosure, the first electrode 841 may be disposed in a portion of the thin film glass 840 corresponding to a folding area FD in which a folding stress is concentrated to easily detect a crack which may occur in the folding area FD.

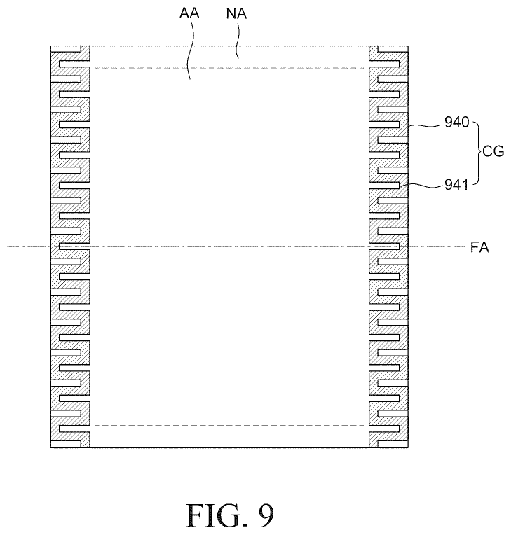

FIG. 9 is a plan view of a cover glass of a display device according to still another exemplary embodiment of the present disclosure. The only difference between a cover glass CG of FIG. 9 and a cover glass CG of the display device 100 of FIGS. 1 to 3 is a first electrode 941, but other configuration is substantially the same, so that a redundant description will be omitted.

Referring to FIG. 9, a first electrode 941 may be disposed at a corner of a top surface of a thin film glass 940 which extends perpendicularly to a folding axis, in the non-active area NA. At this time, the first electrode 941 may be formed in a zigzag pattern.

For example, the first electrode 941 may be formed with a shape in which a plurality of concave portions and a plurality of convex portions are alternately and continuously disposed. When the first electrode 941 has a zigzag pattern, a placement area of the first electrode 941 per unit area on the thin film glass 940 may be increased as compared with a case in which the first electrode 941 is linearly disposed without a separate pattern. Therefore, an area in which a crack may be detected may expand. Accordingly, a crack occurring in the thin film glass 940 may be more easily detected.

In the meantime, unlike the first electrode 941 illustrated in FIG. 9 which extends perpendicular or parallel to a folding direction, when the first electrode 941 has a zigzag pattern which diagonally extends to the folding direction, a stress applied to the first electrode 941 when the display device is folded is relieved to minimize the crack occurring in the first electrode 941.

In the display device according to still another exemplary embodiment of the present disclosure, in the non-active area NA, the first electrode 941 may be disposed on the top surface of the thin film glass 940 to detect the crack of the thin film glass 940. At this time, the liquid crystal of the crack detecting unit may be driven by a voltage difference of the first electrode 941 and the electrode of the crack detecting unit. At this time, when the crack occurs in the area of the thin film glass 940 in which the first electrode 941 is disposed, the liquid crystal of the crack detecting unit is not driven in the area in which the crack occurs. Accordingly, in the display device according to still another exemplary embodiment of the present disclosure, an area in which the liquid crystal of the crack detecting unit is not driven is detected to easily detect the crack of the thin film glass 940.

That is, in the display device according to still another exemplary embodiment of the present disclosure, the first electrode 941 is disposed on a corner of the thin film glass 940 which is specifically vulnerable to the external shocks to suppress the crack from occurring and minimize the penetration of foreign materials through the crack to improve the durability and the reliability.

Specifically, in the display device according to still another exemplary embodiment of the present disclosure, the first electrode 941 is disposed in a direction in which a tensile stress is applied so that it is easy to detect a crack not only in the foldable display device, but also in a slidable or rollable display device.

Further, in the display device according to still another exemplary embodiment of the present disclosure, the first electrode 941 may be formed with a zigzag pattern in which a plurality of concave portions and a plurality of convex portions are alternately and continuously disposed. In this case, a placement area of the first electrode 941 for every unit area is increased to expand an area in which a crack may be detected. Further, if the first electrode 941 has a zigzag shape extending diagonally to a folding direction, when the display device is folded, the folding stress is distributed to relieve the tensile stress. Accordingly, the crack of the first electrode 941 due to the tensile stress is suppressed so that it is more advantageous to detect a crack of the thin film glass 940.

The exemplary embodiments of the present disclosure can also be described as follows:

According to an aspect of the present disclosure, there is provided a display device. The display device includes a flexible substrate including an active area and a non-active area which encloses the active area; a light emitting diode disposed on the flexible substrate; a thin film glass disposed on the light emitting diode; and a first electrode disposed on a top surface of the thin film glass, in the non-active area.

The first electrode may be disposed in the non-active area extending along at least one corner of a top surface of the thin film glass.

The first electrode may be a transparent electrode.

A refractive index of the first electrode may be larger than a refractive index of the thin film glass.

The first electrode may be floating electrode.

The first electrode may be formed of a material including a black metal.

The display device may further comprise an organic layer which is disposed between the thin film glass and the first electrode so as to overlap the first electrode.

A refractive index of the organic layer may be 1.5 to 1.6.

The display device may further comprise a second electrode disposed at a corner of a bottom surface of the thin film glass, in the non-active area.

The display device may further comprise a sub electrode disposed in the first electrode, in the non-active area.

The flexible substrate may include a folding area and non-folding areas on both sides of the folding area, and the first electrode may be disposed in a non-active area of the thin film glass corresponding to the folding area.

The flexible substrate may further include a folding axis and the first electrode has a zigzag shape and may be disposed at a corner extending perpendicular to the folding axis.

A thickness of the thin film glass may be 30 μm or larger and 90 μm or smaller.

The thin film glass may have a chamfered corner.

In the non-active area, a top surface of the thin film glass may include a flat portion adjacent to the active area and an inclined portion which connects a corner of the flat portion and a side surface of the thin film glass and may be inclined at a predetermined angle and the first electrode may be disposed on the inclined portion.

The first electrode may extend to be disposed on the flat portion of the thin film glass in the non-active area.

The display device may further comprise a sub electrode which is spaced apart from the first electrode and is disposed on the flat portion in the non-active area.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a flexible substrate including an active area and a non-active area enclosing the active area;
a light emitting diode disposed on the flexible substrate;
a thin film glass disposed on the light emitting diode; and
a first electrode disposed on a top surface of the thin film glass, in the non-active area.

2. The display device according to claim 1, wherein the first electrode is disposed in the non-active area extending along at least one corner of a top surface of the thin film glass.

3. The display device according to claim 1, wherein the first electrode is a transparent electrode.

4. The display device according to claim 1, wherein a refractive index of the first electrode is larger than a refractive index of the thin film glass.

5. The display device according to claim 1, wherein the first electrode is floating electrode.

6. The display device according to claim 1, wherein the first electrode is formed of a material including a black metal.

7. The display device according to claim 1, further comprising:
an organic layer which is disposed between the thin film glass and the first electrode so as to overlap the first electrode.

8. The display device according to claim 7, wherein a refractive index of the organic layer is 1.5 to 1.6.

9. The display device according to claim 1, further comprising:
a second electrode disposed at a corner of a bottom surface of the thin film glass, in the non-active area.

10. The display device according to claim 1, further comprising:
a sub electrode disposed in the first electrode, in the non-active area.

11. The display device according to claim 1, wherein the flexible substrate includes a folding area and non-folding areas on both sides of the folding area, and the first electrode is disposed in a non-active area of the thin film glass corresponding to the folding area.

12. The display device according to claim 1, wherein the flexible substrate further includes a folding axis, and the first electrode has a zigzag shape and is disposed at a corner extending perpendicular to the folding axis.

13. The display device according to claim 1, wherein a thickness of the thin film glass is 30 μm or larger and 90 μm or smaller.

14. The display device according to claim 1, wherein the thin film glass has a chamfered corner.

15. The display device according to claim 14, wherein in the non-active area, a top surface of the thin film glass includes a flat portion adjacent to the active area and an inclined portion which connects a corner of the flat portion and a side surface of the thin film glass and is inclined at a predetermined angle, and the first electrode is disposed on the inclined portion.

16. The display device according to claim 15, wherein the first electrode extends to be disposed on the flat portion of the thin film glass in the non-active area.

17. The display device according to claim 15, further comprising:
a sub electrode which is spaced apart from the first electrode and is disposed on the flat portion in the non-active area.
